(19) United States
(12) Patent Application Publication
(10) Pub. No.: US 2009/0075480 A1
(43) Pub. Date: Mar. 19, 2009

(54) Silicon Carbide Doped Oxide Hardmask For Single and Dual Damascene Integration

(75) Inventors: Laura M. Matz, Macungie, PA (US); Ping N. Jiang, Plano, TX (US); William Wesley Dostalik, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/856,836

(22) Filed: Sep. 18, 2007

(51) Int. Cl. H01L 21/311

(52) U.S. Cl. 438/694; 257/E21.249

(57) ABSTRACT

Interconnects of integrated circuits (ICs) utilize low-k dielectrics, copper metal lines, dual damascene processing and amplified photoresist chemistry to build ICs with features smaller than 100 nm. Photolithographic processing of interconnects with these elements are subject to resist poisoning from nitrogen in etch stop and hard mask dielectric layers. Attempts to solve this problem cause lower IC circuit performance or higher fabrication process cost and complexity. This invention comprises a method of fabricating interconnects in an IC using layers of silicon carbide doped oxide (SiCO) in a via etch stop layer, in a trench etch stop layer, as a via etch hard mask and as a trench etch hard mask.

### FIELD OF THE INVENTION

This invention relates to the field of integrated circuits. More particularly, this invention relates to integrated circuits with copper interconnects and low-k dielectrics.

### BACKGROUND OF THE INVENTION

It is well known that integrated circuits (ICs) consist of electrical components such as transistors, diodes, resistors and capacitors built into the top layer of a semiconductor wafer, typically a silicon wafer. It is also well known that these components are electrically connected to form useful circuits by metal interconnects consisting of several layers of horizontal metal lines and vertical metal vias, separated by dielectric materials. A major concern in interconnect fabrication is to minimize the resistance and capacitance of the interconnects in order to maximize the operating speed of the circuits in the ICs. Copper metal is used to form the interconnects, because copper has lower electrical resistance than the previously used interconnect metal, aluminum. Additionally, the dielectric materials with lower dielectric constants than silicon dioxide, such as organo-silicate glass, collectively known as low-k dielectric materials, are used to electrically insulate copper interconnects from each other. Low-k dielectric materials achieve their low dielectric constants (relative to silicon dioxide) by using several techniques; one technique is substitution of lighter elements for silicon and oxygen; another is increased porosity (voids have a dielectric constant very close to 1.00). Most low-k dielectric materials utilize both of these techniques.

Regions in the dielectric layers for horizontal metal lines and vertical metal vias are etched to remove the dielectric material, prior to depositing metal in the desired regions. Maintaining well defined patterns for interconnects during etching is challenging.

Layers of denser, more etch resistant dielectric, known as hard masks are deposited on low-k dielectric layers to maintain desired lateral dimensions of interconnect patterns during etching. There are several requirements of hard mask layers. One requirement is an ability to withstand an etch cycle which removes low-k dielectric material down to a lower metal level. Another is to minimize remaining hard mask material after etching is completed, to minimize capacitive coupling between adjacent metal lines. A third is to provide good adhesion to photolithographic materials, typically an organic anti-reflective material, known as BARC (bottom anti-reflective coating). To meet these requirements, a layer of silicon nitride or silicon carbide nitride is often used with a layer of silicon dioxide for adhesion to BARC.

It is also well known that the lateral dimensions of components in ICs, including interconnect linewidths and via diameters, are on a downward trend over time. The minimum interconnect feature sizes, known as critical dimensions (CDs), of recent ICs are below 100 nm. These features are defined photolithographically with light that has wavelengths close to the desired CD, using photoresists that can convert said light into a well defined mask for etching underlying layers. Photoresists rely on amine compounds to convert molecules that are insoluble in a photodeveloper to molecules that are soluble in the developer. These resists are commonly known as amplified resists. A problem arises with the use of dielectric layers containing nitrogen, such as silicon nitride, in combination with low-k dielectrics and amplified resists. Nitrogen can diffuse out of the nitrogen containing dielectric film into the low-k dielectric material and into the photoresist, and interfere with the proper action of the amine molecules in the amplified photoresist. This phenomenon is known as resist poisoning. Resist poisoning can distort the photolithographically defined features of interconnects, resulting in narrow or interrupted horizontal metal lines, which in turn cause circuit failures and reliability problems. This problem is often addressed by providing an additional layer to hard mask stacks, comprising a layer, typically composed of silicon dioxide, to retard diffusion of nitrogen from other hard mask layers into low-k dielectric materials.

Photoresist thickness is significantly reduced by etching through hard mask layers, because three layers require significant time to etch through. This is disadvantageous because loss of photoresist imposes tighter requirements on control of lateral dimensions in via patterning, which increases cost and complexity of via patterning.

Photoresist thickness is reduced even more by etching through low-k dielectric material, and photoresist may be completely removed before low-k dielectric etching is completed. This is disadvantageous because loss of photoresist degrades the topography of hard mask layers around etched regions, for example via regions in a via-first process, which degrades the profile of metal trench in an ensuing trench etch.

Nitrogen containing films in via etch stop layers can also contribute to resist poisoning. Adding nitrogen blocking layer to via etch stop stacks results in more difficult etch control and increased capacitive coupling between adjacent metal lines.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

This invention comprises a method for forming an integrated circuit comprising a silicon carbide doped oxide (SiCO) film for use in single and dual damascene copper interconnect fabrication. The SiCO film of this invention is formed using various gases, including 100 to 2000 sccm hydrogen, 100 to 2000 sccm helium, 100 to 2000 sccm tri-methyl silane and 100 to 1000 sccm carbon dioxide, resulting in a stoichiometry of 28 to 46 atomic percent silicon, 26 to 44 atomic percent carbon, 19 to 35 atomic percent oxygen. In one embodiment, a layer of SiCO replaces multiple layer metal hard masks. In another embodiment, a layer of SiCO is added to via etch stop layer stacks.

### DESCRIPTION OF THE VIEWS OF THE DRAWING

FIG. 1A is a fragmentary, diagrammatic sectional view on an enlarged scale of a cross-section of an integrated circuit including MOS transistors and metal 1, via 1 and metal 2 interconnect regions in embodiments of the instant invention, depicted after via 1 pattern in a dual damascene full via-first process sequence.

FIG. 1B is a fragmentary, diagrammatic sectional view on an enlarged scale of a cross-section of an integrated circuit including MOS transistors and metal 1, via 1 and metal 2 interconnect regions in embodiments of the instant invention, depicted after etching through a metal 2 hard mask in a dual damascene full via-first process sequence.

FIG. 1C is a fragmentary, diagrammatic sectional view on an enlarged scale of a cross-section of an integrated circuit including MOS transistors and metal 1, via 1 and metal 2 interconnect regions in embodiments of the instant invention, depicted after etching a via 1 hole in a dual damascene full via-first process sequence.

FIG. 1D is a fragmentary, diagrammatic sectional view on an enlarged scale of a cross-section of an integrated circuit including MOS transistors and metal 1, via 1 and metal 2 interconnect regions in embodiments of the instant invention, depicted after etching metal 2 trench and via 1 etch stop in a dual damascene full via-first process sequence.

FIG. 2 is a fragmentary, diagrammatic sectional view on an enlarged scale of a cross-section of an integrated circuit including MOS transistors and metal 1, via 1 and metal 2 interconnect regions in embodiments of the instant invention, depicted after etching metal 2 trench in a single damascene process sequence.

### DETAILED DESCRIPTION

Silicon carbide doped oxide (SiCO) films are generated in a plasma reactor using gases that include 100 to 2000 standard cubic centimeters per minute (sccm) of hydrogen, 100 to 2000 sccm of helium, 100 to 2000 sccm of tri-methyl silane and 100 to 1000 sccm of carbon dioxide. A plasma comprising these gases is maintained at 200 to 900 watts of RF power, at a pressure of 2 to 8 torr. The stoichiometry of the resulting SiCO film is 28 to 46 atomic percent silicon, 26 to 44 atomic percent carbon, 19 to 35 atomic percent oxygen, and less than 2 atomic percent of other elements (if present) such as nitrogen, hydrogen, etc.

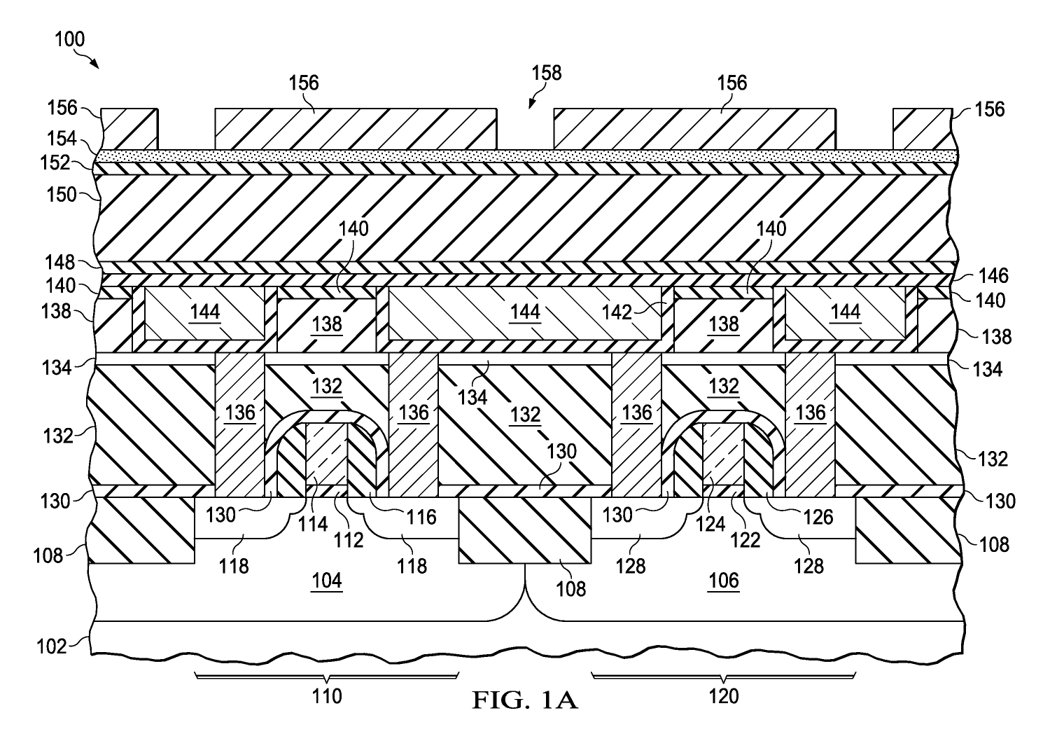

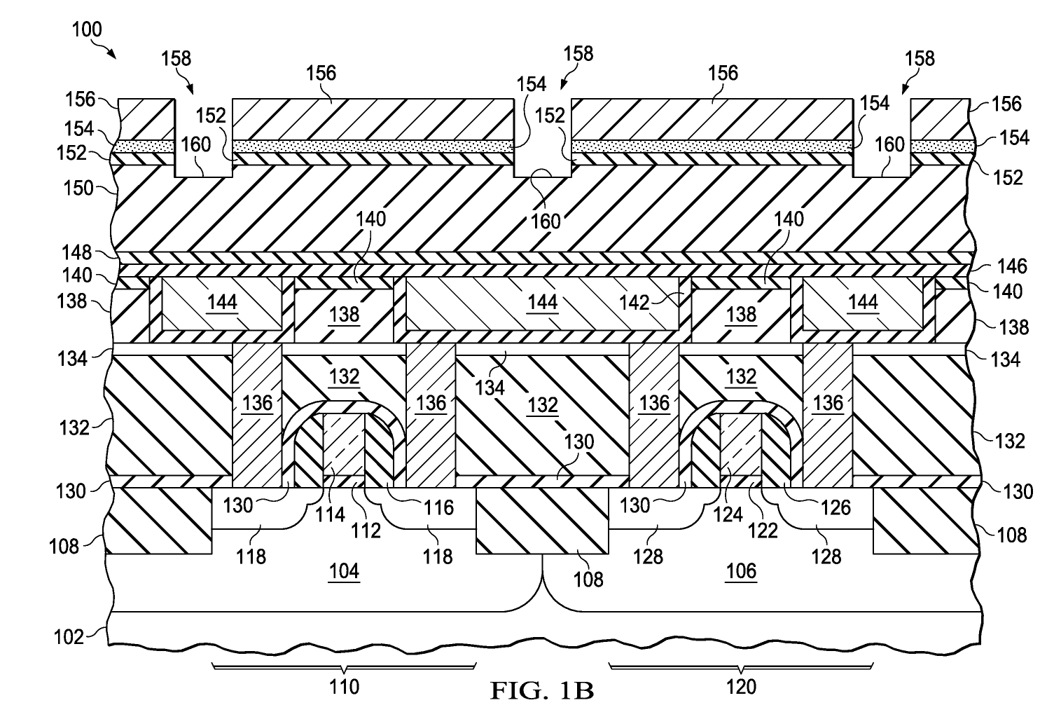

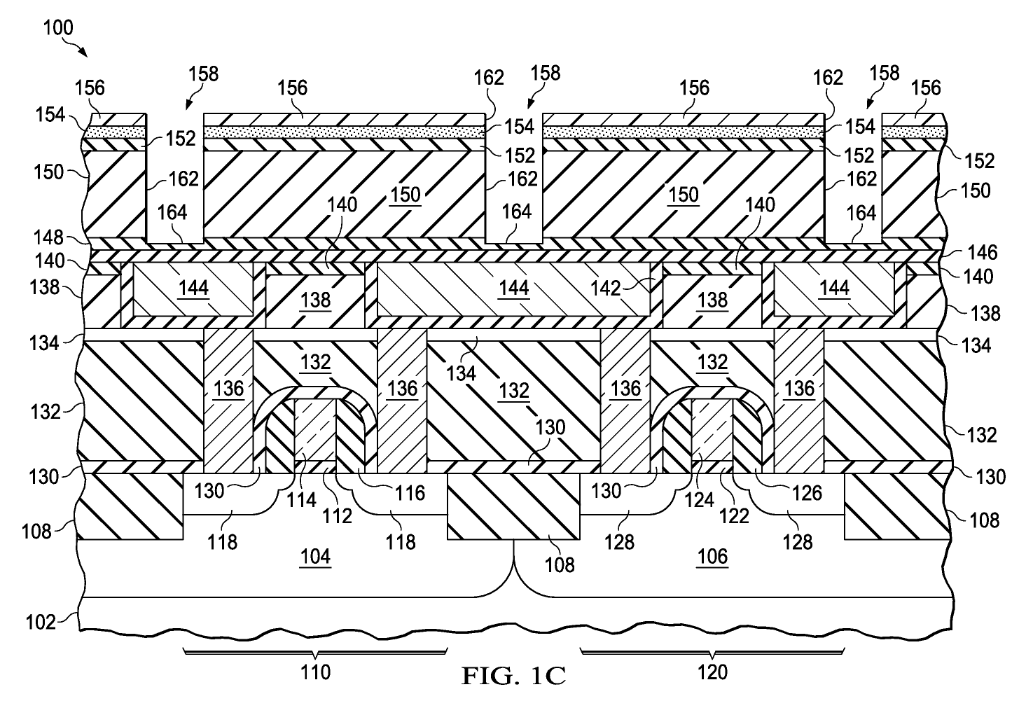

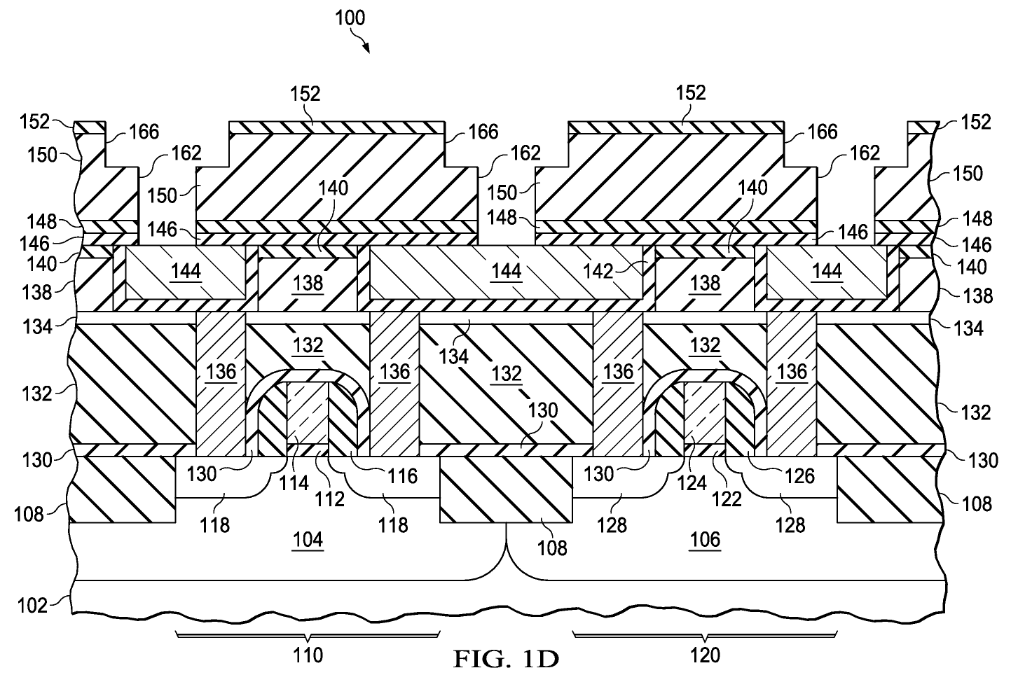

FIG. 1A is a fragmentary, diagrammatic sectional view on an enlarged scale of a cross-section of an integrated circuit including MOS transistors and metal 1, via 1 and metal 2 interconnect regions in embodiments of the instant invention, depicted after via 1 pattern in a dual damascene full via-first process sequence. An IC (100) provides a substrate (102), in which are formed an n-type region known as an n-well (104) and a p-type region known as a p-well (106). Components in the IC (100) are electrically isolated by field oxide (108), typically composed of silicon dioxide, and typically formed by local oxidation of silicon (LOCOS) or shallow trench isolation (STI). In said p-well is formed an n-channel MOS (NMOS) transistor (110), comprising an n-channel gate dielectric (112), n-channel gate (114), n-channel sidewall spacer (116) and n-channel source and drain regions (118). Similarly, in said n-well is formed an p-channel MOS (PMOS) transistor (120), comprising an p-channel gate dielectric (122), p-channel gate (124), p-channel sidewall spacer (126) and p-channel source and drain regions (128).

Still referring to FIG. 1A, a pre-metal dielectric (PMD) layer stack is formed on a top surface of the IC, comprising a PMD liner (130), a PMD (132) and contact cap layer (134). Electrical connection to the NMOS and PMOS transistors is made by contacts (136), typically comprised of tungsten, formed through the PMD liner (130), PMD (132) and contact cap layer (134). On a top surface of the contacts (136) and contact cap layer (134) is formed intra-level 1 low-k dielectric (138) and metal 1 hard mask (140), and metal 1 comprising metal 1 liner metal (142) and metal 1 fill metal (144), typically copper. A via 1 etch stop first dielectric (146), typically silicon carbide nitride, is deposited, followed by a layer of silicon carbide doped oxide (SiCO) (148), 10 to 60 nanometers thick, in accordance with an embodiment of the instant invention, which acts as a nitrogen blocking layer to prevent nitrogen in the via 1 etch stop first dielectric (146) from contributing to resist poisoning. The SiCO layer (148) also serves as a part of a via 1 etch stop, allowing a thin layer of via 1 etch stop first dielectric (144) to be used. A layer of intra-level 1 dielectric (150), typically low-k material, is deposited over the via 1 etch stop first dielectric and via 1 etch stop second dielectric layers. A metal 2 hard mask layer (152) is comprised of a single layer of SiCO, 5 to 100 nanometers thick, in accordance with another embodiment of the instant invention. BARC (154) and photoresist (156) layers are formed, and a via 1 pattern (158) is defined photolithographically.

FIG. 1B is a fragmentary, diagrammatic sectional view on an enlarged scale of a cross-section of an integrated circuit including MOS transistors and metal 1, via 1 and metal 2 interconnect regions in embodiments of the instant invention, depicted after etching through a metal 2 hard mask in a dual damascene full via-first process sequence. The metal 2 hard mask layer (152) has been etched in via 1 regions (160) as defined by a photoresist pattern (158). The as deposited thickness of the photoresist (156) is maintained during the SiCO hard mask etching, due to the reduced time it takes to etch through a single layer of SiCO. This is advantageous because retention of more photoresist allows more process margin (coating thickness, exposure and depth of focus range) in via 1 patterning processes, reducing costs and improving yields during IC fabrication.

FIG. 1C is a fragmentary, diagrammatic sectional view on an enlarged scale of a cross-section of an integrated circuit including MOS transistors and metal 1, via 1 and metal 2 interconnect regions in embodiments of the instant invention, depicted after etching a via 1 hole in a dual damascene full via-first process sequence. A via 1 hole (162) has been extended down to the via 1 etch stop 2 layer (148), forming a slight recess (164) in the SiCO layer of the via 1 etch stop 2 dielectric (148). Some photoresist (156) may remain after via etch.

FIG. 1D is a fragmentary, diagrammatic sectional view on an enlarged scale of a cross-section of an integrated circuit including MOS transistors and metal 1, via 1 and metal 2 interconnect regions in embodiments of the instant invention, depicted after etching metal 2 trench and via 1 etch stop in a dual damascene full via-first process sequence. Trench patterning does not suffer from resist poisoning because the SiCO via 1 etch stop second dielectric (148) blocks the nitrogen from the underlying via 1 etch stop first dielectric (146). The via stop etch process removed the etch stop materials (146, 148) in a via hole (162) down to the metal 1 fill metal (144). SiCO, as used in the via 1 etch stop second dielectric (148), has a better selectivity to the via etch, so a thinner layer of via 1 etch stop first dielectric (146) can be used. This is advantageous, because it produces less undercutting of a trench profile (166) in the low-k dielectric, which increases process margins of a metal 2 liner metal deposition process. The SiCO hard mask layer (152) is thinner than the SiO2 nitrogen blocking layer used currently and is advantageous, because it also increases the process margins of the metal 2 liner metal deposition process.

It will be readily apparent to practitioners of integrated circuit fabrication that the advantages of a SiCO via etch stop layer and a SiCO single layer hard mask are applicable to all interconnect levels comprising low-k dielectrics, dual damascene processing, amplified photoresist processing and nitrogen bearing dielectrics in via etch stop layers.

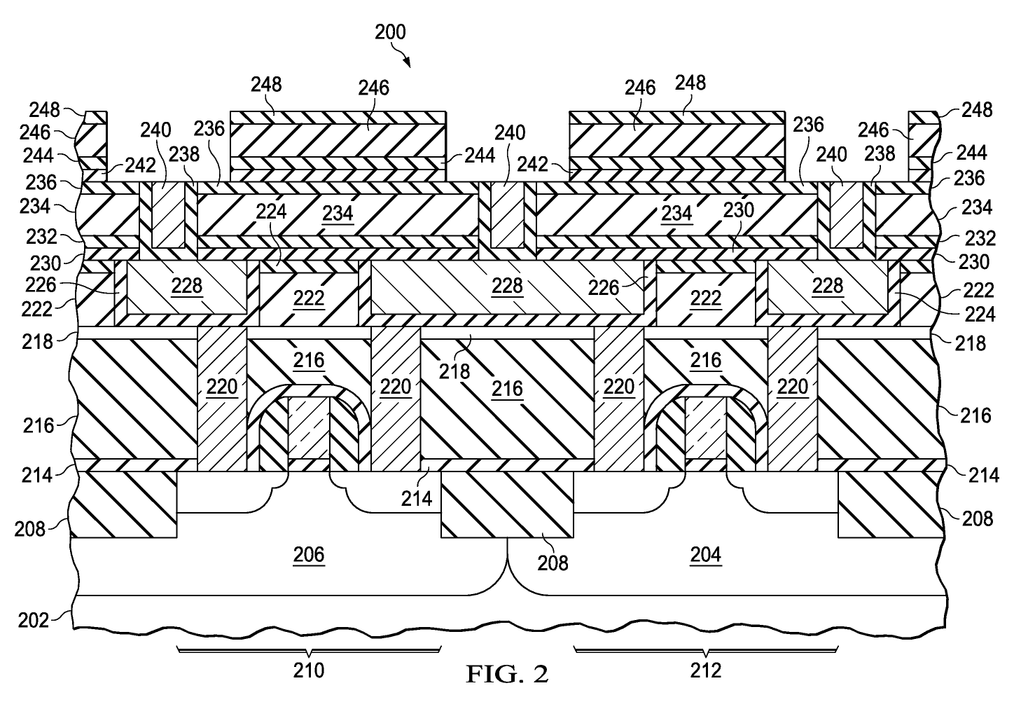

It will also be apparent to practitioners of integrated circuit fabrication that the advantages of a SiCO etch stop layer and a SiCO single layer hard mask are applicable when implemented in a single damascene process. FIG. 2 is a fragmentary, diagrammatic sectional view on an enlarged scale of a cross-section of an integrated circuit including MOS transistors and metal 1, via 1 and metal 2 interconnect regions in embodiments of the instant invention, depicted after etching metal 2 trench in a single damascene process sequence. An IC (200) provides a substrate (202), in which are formed an n-type region known as an n-well (204) and a p-type region known as a p-well (206). Components in the IC (200) are electrically isolated by field oxide (208), typically composed of silicon dioxide, and typically formed by local oxidation of silicon (LOCOS) or shallow trench isolation (STI). In said p-well is formed an n-channel MOS (NMOS) transistor (210). Similarly, in said n-well is formed a p-channel MOS (PMOS) transistor (212). A pre-metal dielectric (PMD) layer stack is formed on a top surface of the IC, comprising a PMD liner (214), a PMD (216) and contact cap layer (218). Electrical connection to the NMOS and PMOS transistors is made by contacts (220), typically comprised of tungsten, formed through the PMD liner (214), PMD (216) and contact cap layer (218). On a top surface of the contacts (220) and contact cap layer (218) is formed intra-level 1 low-k dielectric (222) and metal 1 hard mask (224), and metal 1 comprising metal 1 liner metal (226) and metal 1 fill metal (228), typically copper. A via 1 etch stop first dielectric (230), typically silicon carbide nitride, is deposited, followed by a via 1 etch stop second dielectric (232) comprised of a layer of silicon carbide doped oxide (SiCO), 10 to 60 nanometers thick, in accordance with an embodiment of the instant invention, which acts as a nitrogen blocking layer to prevent nitrogen in the via 1 etch stop first dielectric (230) from contributing to resist poisoning. The use of SiCO in the via 1 etch stop second dielectric (232) allows a thin layer of via 1 etch stop first dielectric (230) to be used. A layer of inter-level 1 dielectric (234), typically low-k material, is deposited over the via 1 etch stop first dielectric and via 1 etch stop second dielectric layers. A via 1 hard mask layer (236) is comprised of a single layer of SiCO, 5 to 100 nanometers thick, in accordance with another embodiment of the instant invention. A set of via 1 interconnects are formed by etching defining via 1 regions photolithographically and etching through the via 1 hard mask layer (236), inter-level 1 dielectric (234) and via 1 etch stop first and second dielectric layers (232, 230), depositing via 1 liner metal (238) and via 1 fill metal (240), typically copper. A trench 2 etch stop first dielectric (242), typically silicon carbide nitride, is deposited, followed by a trench 2 etch stop second dielectric (244), comprised of a layer of silicon carbide doped oxide (SiCO), 10 to 60 nanometers thick, in accordance with an embodiment of the instant invention, which acts as a nitrogen blocking layer to prevent nitrogen in the trench 2 etch stop first dielectric (242) from contributing to resist poisoning. The use of SiCO in the trench 2 etch stop second dielectric (244) allows a thin layer of trench 2 etch stop first dielectric (242) to be used. A layer of intra-level 2 dielectric (246), typically low-k material, is deposited over the trench 2 etch stop first dielectric (242) and trench 2 etch stop second dielectric (244) layers. A trench 2 hard mask layer (248) is comprised of a single layer of SiCO, 5 to 100 nanometers thick, in accordance with another embodiment of the instant invention. Trench 2 regions are defined photolithographically and etched through the trench 2 hard mask layer (248), intra-level 2 dielectric (246), and trench 2 etch stop first and second dielectrics (242, 244).

What is claimed is:

1. A method of forming an integrated circuit comprising the steps of:
providing a substrate;
forming a transistor in the substrate;
forming a first electrically insulating layer over the transistor;
forming a first set of copper metal interconnects in the first electrically insulating layer;
forming a first layer of a silicon carbide doped oxide film over the first set of copper metal interconnects, said silicon carbide doped oxide film being formed by a process comprising the steps of:
positioning the substrate in a plasma reactor;
flowing 100 to 2000 sccm (standard cubic centimeters per minute) of hydrogen gas into said plasma reactor;
flowing 100 to 2000 sccm of helium gas into said plasma reactor;
flowing 100 to 2000 sccm of tri-methyl silane gas into said plasma reactor;
flowing 100 to 1000 sccm of carbon dioxide gas into said plasma reactor;
generating a plasma comprising the hydrogen, helium, tri-methyl silane and carbon dioxide gases in the plasma reactor;
maintaining the plasma at 200 to 900 watts of RF power; and
maintaining a pressure of 2 to 8 torr in the plasma reactor;
forming a second electrically insulating layer over the first layer of said silicon carbide doped oxide film;
forming a first layer of photoresist over the second electrically insulating layer;
patterning the first layer of photoresist to define a first set of via regions; and
etching the second electrically insulating layer in the first set of via regions, wherein the first layer of said silicon carbide doped oxide film is exposed in the first set of via regions.

2. The method of claim 1, wherein said first layer of said silicon carbide doped oxide film is 10 to 60 nanometers thick.

3. The method of claim 1, wherein said integrated circuit is fabricated using dual damascene processing.

4. The method of claim 1, wherein said integrated circuit is fabricated using single damascene processing.

5. A method of forming an integrated circuit comprising the steps of:
providing a substrate;
forming a transistor in the substrate;
forming a first electrically insulating layer over the transistor;
forming a first layer of a silicon carbide doped oxide film over the first electrically insulating layer, said silicon carbide doped oxide film being formed by a process comprising the steps of:
positioning the substrate in a plasma reactor;
flowing 100 to 2000 sccm (standard cubic centimeters per minute) of hydrogen gas into said plasma reactor;
flowing 100 to 2000 sccm of helium gas into said plasma reactor;
flowing 100 to 2000 sccm of tri-methyl silane gas into said plasma reactor;
flowing 100 to 1000 sccm of carbon dioxide gas into said plasma reactor;
generating a plasma comprising the hydrogen, helium, tri-methyl silane and carbon dioxide gases in the plasma reactor;
maintaining the plasma at 200 to 900 watts of RF power; and
maintaining a pressure of 2 to 8 torr in the plasma reactor;
forming a first layer of photoresist over the first layer of said silicon carbide doped oxide film;
patterning the first layer of photoresist to define a first set of via regions;
etching the first layer of said silicon carbide doped oxide film in the first set of via regions; and
etching the first electrically insulating layer in the first set of via regions.

6. The method of claim 5, further comprising the steps of:
forming a second layer of photoresist over the first layer of said silicon carbide doped oxide film;
patterning the second layer of photoresist to define a first set of metal interconnect trench regions;
etching the first layer of said silicon carbide doped oxide film in the first set of metal interconnect trench regions; and
etching the first electrically insulating layer in the first set of metal interconnect trench regions.

7. The method of claim 5, wherein said first layer of said silicon carbide doped oxide film is 5 to 100 nanometers thick.

8. The method of claim 5, wherein said integrated circuit is fabricated using dual damascene processing.

9. The method of claim 5, wherein said integrated circuit is fabricated using single damascene processing.

10. A method of forming an integrated circuit comprising the steps of:
providing a substrate;
forming a transistor in the substrate;
forming a first electrically insulating layer over the transistor;
forming a first set of copper vias in the first electrically insulating layer;
forming a first layer of a silicon carbide doped oxide film over the first set of copper vias, said silicon carbide doped oxide film being formed by a process comprising the steps of:
positioning the substrate in a plasma reactor;
flowing 100 to 2000 sccm (standard cubic centimeters per minute) of hydrogen gas into said plasma reactor;
flowing 100 to 2000 sccm of helium gas into said plasma reactor;
flowing 100 to 2000 sccm of tri-methyl silane gas into said plasma reactor;
flowing 100 to 1000 sccm of carbon dioxide gas into said plasma reactor;
generating a plasma comprising the hydrogen, helium, tri-methyl silane and carbon dioxide gases in the plasma reactor;
maintaining the plasma at 200 to 900 watts of RF power; and
maintaining a pressure of 2 to 8 torr in the plasma reactor;
forming a second electrically insulating layer over the first layer of said silicon carbide doped oxide film;
forming a first layer of photoresist over the second electrically insulating layer;
patterning the first layer of photoresist to define a first set of metal interconnect trench regions; and
etching the second electrically insulating layer in the first set of via regions, wherein the first layer of said silicon carbide doped oxide film is exposed in the first set of metal interconnect trench regions.

11. The method of claim 10, wherein said first layer of said silicon carbide doped oxide film is 10 to 60 nanometers thick.

12. The method of claim 10, wherein said integrated circuit is fabricated using dual damascene processing.

13. The method of claim 10, wherein said integrated circuit is fabricated using single damascene processing.
